(19) United States
(12) Patent Application Publication
(10) Pub. No.: US 2009/0065842 A1
(43) Pub. Date: Mar. 12, 2009

(54) Ta-lined tungsten plugs for transistor-local hydrogen gathering

(76) Inventor: Matthew Buynoski, Palo Alto, CA (US)

Correspondence Address: Paul J. Winters, 307 Cypress Point Drive, Mountain View, CA, 94043, US

(21) Appl. No.: 11/899,575

(22) Filed: Sep. 6, 2007

(51) Int. Cl. H01L 23/52; H01L 21/44; H01L 29/788

(52) U.S. Cl. 257/315; 257/761; 438/660; 257/E23.141; 257/E21.476; 257/E29.3

(57) ABSTRACT

The present electronic device includes a dielectric body having an opening therein. A tantalum layer is provided in the opening of the dielectric body, the layer having the characteristic of absorbing hydrogen with decrease in temperature, and releasing hydrogen with increase in temperature. A conductive tungsten plug is provided on the layer in the opening.

### BACKGROUND OF THE INVENTION

1. Technical Field

This invention relates generally to electronic devices, and more particularly, to an approach for gathering hydrogen therein.

2. Background Art

FIGS. 1-6 illustrate an approach for forming an interconnect in the form of a tungsten plug, one of a large number thereof in an electronic device 20. FIG. 1 illustrates a flash memory device in 22, which includes a silicon substrate 24 having a source 26 and a drain 28 formed therein, with silicide contacts 30, 32 formed on the respective source 26 and drain 28. The substrate 24 has formed thereon, in successive layers, tunnel oxide 34, charge storage layer 36, ONO layer 38, and control gate 40, as is well known (FIG. 1). Referring to FIG. 2, a dielectric layer 42, for example silicon dioxide, is deposited over the structure of FIG. 1, and using patterned photoresist (not shown) on the dielectric layer 42, an opening 44 is provided therethrough to the silicide 32 on the drain 28. After removal of the photoresist, a thin titanium layer 46 is deposited on the resulting structure (FIG. 3), on the surfaces 42A, 42B of the dielectric layer 42, in the opening 44, and in contact with the silicide 32. The titanium layer 46 is included to provide ohmic contact with the silicide 32. Tungsten 48 is then deposited over and in contact with the layer 46 and in the opening 44 (also FIG. 3).

Next, a chemical-mechanical polishing step is undertaken to remove the portions of the layer 46 and tungsten 48 from over the surfaces 42A, 42B of the dielectric layer 42, leaving tungsten plug 50 on and in contact with the layer 46 and within the opening 44 (FIG. 4). FIG. 5 illustrates formation of a metal line 52 over the resulting structure, in conductive contact with the plug 50. In further accordance with FIG. 5, a silicon nitride layer 54 is deposited over the resulting structure.

In the example given, hydrogen may be formed as a byproduct in processing steps (for example plasma etching). In addition, hydrogen may be released from the dielectric layer 22 and the silicon nitride layer 54 (both of which are excellent reservoirs of hydrogen) during a high temperature thermal cycle. Titanium has the characteristic of absorbing hydrogen upon increase in temperature thereof, and releasing hydrogen upon decrease in temperature thereof. FIG. 5 illustrates hydrogen (H₂) moving into and being held by the titanium layer 46 during a high-temperature processing step. During the subsequent cooling step, this level of hydrogen can no longer be retained by the titanium layer 46, and some hydrogen is released or expelled thereby into the surrounding area (FIG. 6). As will be seen, the charge storage layer 36 is very close to the layer 46, so that hydrogen released from the layer 46 may well travel into the charge storage layer 36, causing instability and inconsistency of operation of the memory device 22.

What is needed an approach which overcomes the above-cited problem.

### DISCLOSURE OF THE INVENTION

Broadly stated, the present electronic device comprises a dielectric body having an opening therein, a layer in the opening of the dielectric body, the layer having the characteristic of absorbing hydrogen with decrease in temperature of the layer, and a conductive plug in the opening.

The present invention is better understood upon consideration of the detailed description below, in conjunction with the accompanying drawings. As will become readily apparent to those skilled in the art from the following description, there is shown and described an embodiment of this invention simply by way of the illustration of the best mode to carry out the invention. As will be realized, the invention is capable of other embodiments and its several details are capable of modifications and various obvious aspects, all without departing from the scope of the invention. Accordingly, the drawings and detailed description will be regarded as illustrative in nature and not as restrictive.

### BRIEF DESCRIPTION OF THE DRAWINGS

The novel features believed characteristic of the invention are set forth in the appended claims. The invention itself, however, as well as said preferred mode of use, and further objects and advantages thereof, will best be understood by reference to the following detailed description of an illustrative embodiment when read in conjunction with the accompanying drawings, wherein:

FIGS. 1-6 illustrate a prior art approach in fabricating a tungsten interconnect in an electronic device;

FIGS. 7-12 illustrate the present approach in fabricating a tungsten interconnect in an electronic device; and

FIGS. 13-15 illustrates systems incorporating the present device.

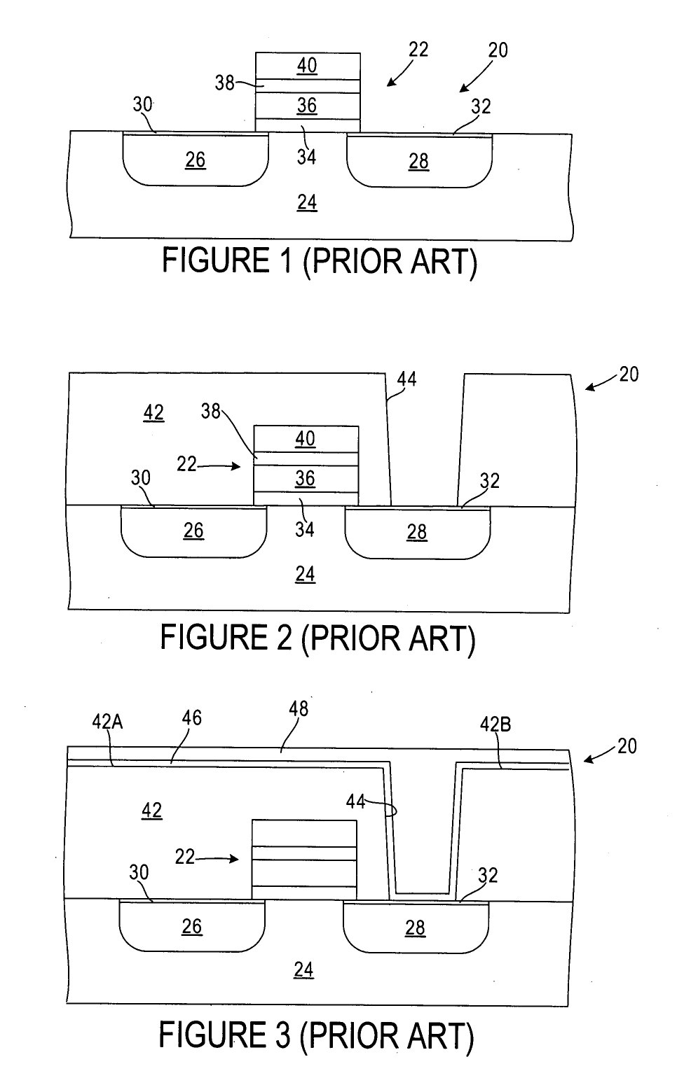

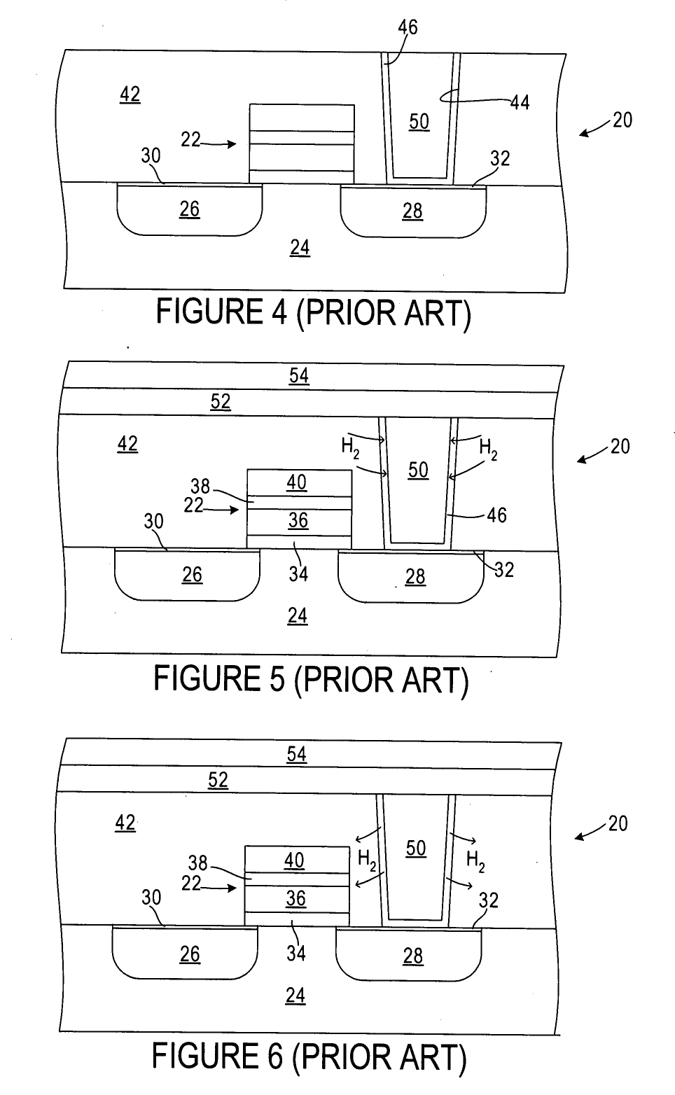

### BEST MODE(S) FOR CARRYING OUT THE INVENTION

Reference is now made in detail to a specific embodiment of the present invention which illustrates the best mode presently contemplated by the inventor for practicing the invention.

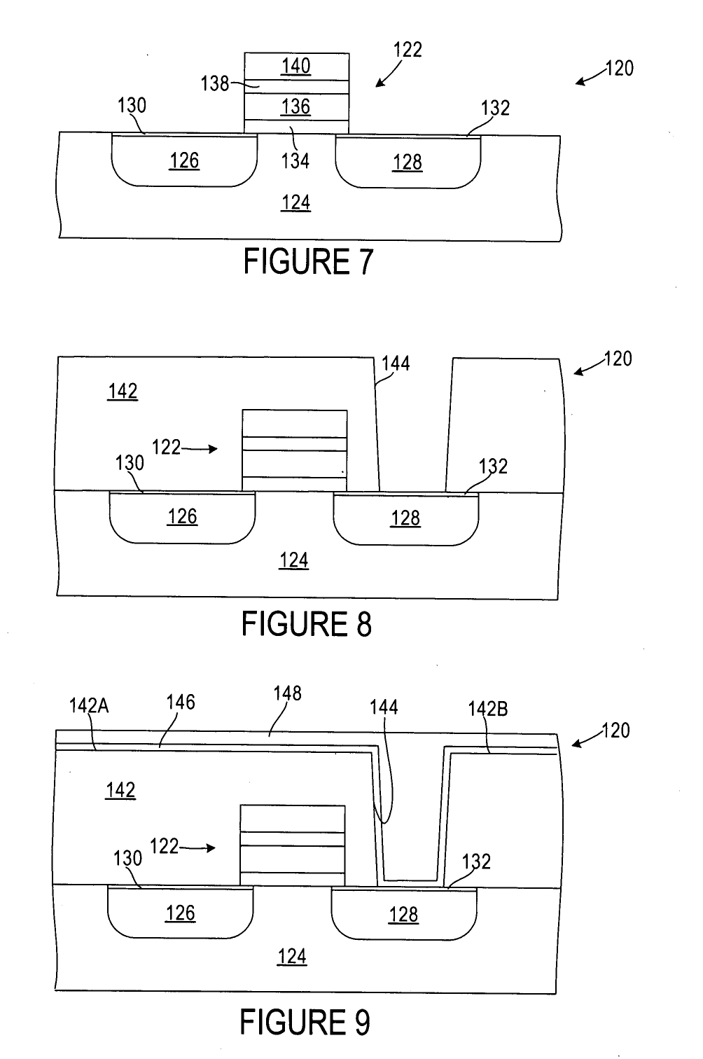

FIGS. 7-12 illustrate the present approach for forming an interconnect in the form of a tungsten plug, one of a large number thereof in an electronic device 120. Similar to the above, FIG. 7 illustrates a flash memory device 122, which includes a silicon substrate 124 having a source 126 and a drain 128 formed therein, with silicide contacts 130, 132 formed on the respective source 126 and drain 128. The substrate 124 has formed thereon, in successive layers, tunnel oxide 134, charge storage layer 136, ONO layer 138, and control gate 140, as is well known (FIG. 7). Referring to FIG. 8, a dielectric layer 142, for example silicon dioxide, is deposited over the structure of FIG. 7, and using patterned photoresist (not shown) on the dielectric layer 142, an opening 144 is provided therethrough to the silicide 132 on the drain 120. After removal of the photoresist, a thin tantalum layer 146 is deposited on the resulting structure (FIG. 9), on the surfaces 142A, 142B of the dielectric layer 142, in the opening 144, and in contact with the silicide 132. The tantalum layer 146 provides ohmic contact with the silicide 132. Tungsten 148 is then deposited over and in contact with the layer 146 and in the opening 144 (also FIG. 9).

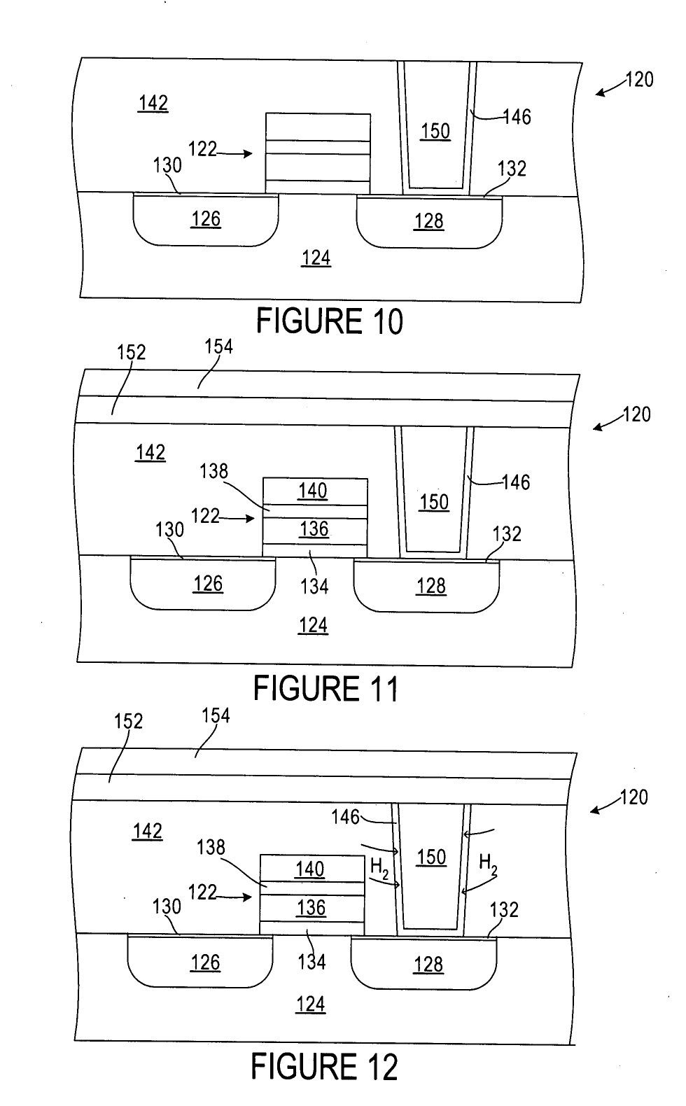

Next, a chemical-mechanical polishing step is undertaken to remove the portions of the tantalum layer 146 and tungsten 148 from over the surfaces 142A, 142B of the dielectric layer 142, leaving tungsten plug 150 on and in contact with the layer 146 and within the opening 144 (FIG. 10). FIG. 11 illustrates formation of a metal line 152 over the resulting structure, in conductive contact with the plug 150. In further accordance with FIG. 11, a silicon nitride layer 154 is deposited over the resulting structure.

In the example given, again, hydrogen may be formed as a byproduct in processing steps (for example plasma etching). In addition, hydrogen may be released from the dielectric layer 142 and the silicon nitride layer 154 (both of which are excellent reservoirs of hydrogen) during a high temperature thermal cycle. Tantalum has the characteristic of releasing hydrogen therefrom upon increase in temperature thereof, and absorbing hydrogen upon decrease in temperature thereof, the opposite of titanium. During the subsequent cooling step, hydrogen is absorbed by the tantalum layer 146 (FIG. 12), drawing the hydrogen away from the flash memory device 122 (and particularly away from the charge storage layer 136). Thus, hydrogen which might have entered the charge storage layer 136 during the cooling step (which would interfere with the proper operation of the memory device as described above) is instead absorbed and held by the tantalum layer 146.

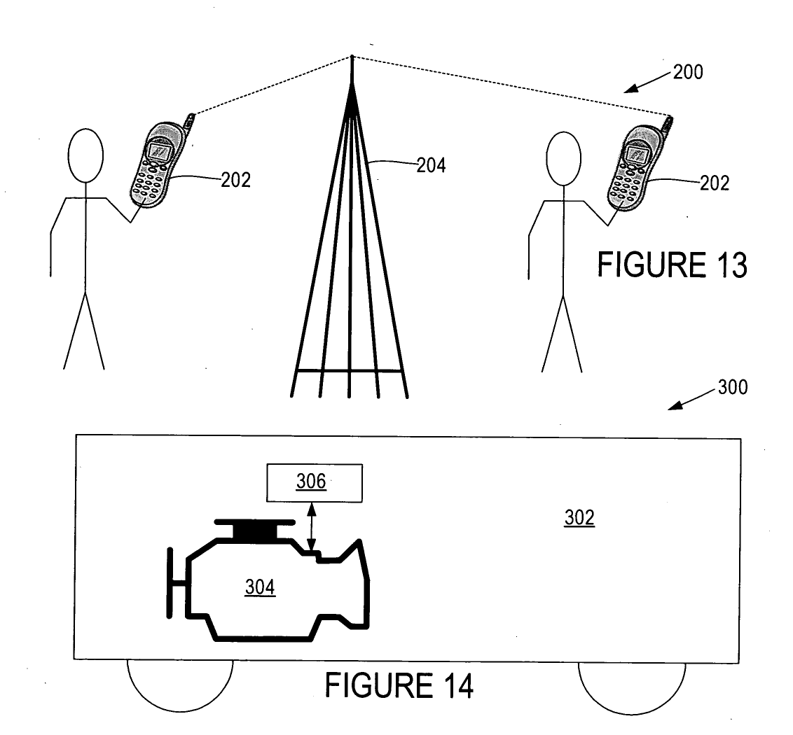

FIG. 13 illustrates a system 200 utilizing devices as described above. As shown therein, the system 200 includes hand-held devices 202 in the form of cell phones, which communicate through an intermediate apparatus such as a tower 204 (shown) and/or a satellite. Signals are provided from one cell phone to the other through the tower 204. Such a cell phone with advantage uses devices of the type described above. One skilled in the art will readily understand the advantage of using such devices in other hand-held devices 202.

FIG. 14 illustrates another system 300 utilizing devices as described above. The system 300 includes a vehicle 302 having an engine 304 controlled by an electronic control unit 306. The electronic control unit 306 with advantage uses devices of the type described above.

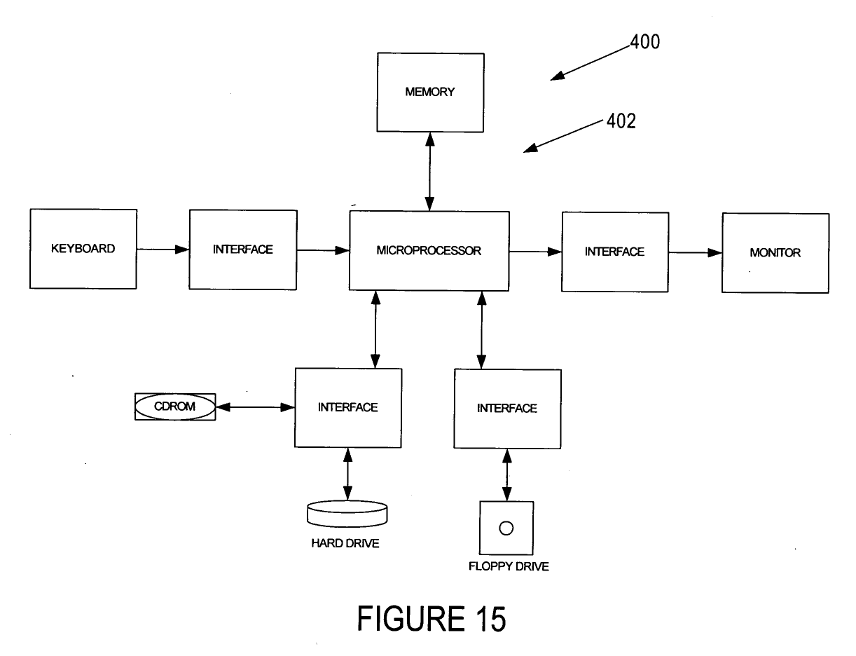

FIG. 15 illustrates yet another system 400 utilizing devices as described above. This system 400 is a computer 402 which includes an input in the form of a keyboard, and a microprocessor for receiving signals from the keyboard through an interface. The microprocessor also communicates with a CDROM drive, a hard drive, and a floppy drive through interfaces. Output from the microprocessor is provided to a monitor through an interface. Also connected to and communicating with the microprocessor is memory which may take the form of ROM, RAM, flash and/or other forms of memory. The system with advantage uses devices of the type described above.

The foregoing description of the embodiment of the invention has been presented for purposes of illustration and description. It is not intended to be exhaustive or to limit the invention to the precise form disclosed. Other modifications or variations are possible in light of the above teachings.

The embodiment was chosen and described to provide the best illustration of the principles of the invention and its practical application to thereby enable one of ordinary skill of the art to utilize the invention in various embodiments and with various modifications as are suited to the particular use contemplated. All such modifications and variations are within the scope of the invention as determined by the appended claims when interpreted in accordance with the breadth to which they are fairly, legally and equitably entitled.

What is claimed is:

1. An electronic device comprising:
a dielectric body having an opening therein;
a layer in the opening of the dielectric body, the layer having the characteristic of absorbing hydrogen with decrease in temperature of the layer; and
a conductive plug in the opening.

2. The device of claim 1 wherein the layer has the characteristic of releasing hydrogen therefrom with increase in temperature of the layer

3. The device of claim 1 wherein the conductive plug is in contact with the layer.

4. The device of claim 1 wherein the layer is a conductive layer.

5. The device of claim 4 wherein the layer comprises tantalum.

6. The device of claim 5 wherein the conductive plug comprises tungsten.

7. The device of claim 1 wherein the dielectric body comprises silicon dioxide.

8. The device of claim 1 and further comprising a memory device adjacent to the layer.

9. The device of claim 8 wherein the memory device is a flash memory device.

10. A method of fabricating an electronic device comprising:
providing a dielectric body;
providing an opening in the dielectric body;
providing a layer in the opening of the dielectric body, the layer having the characteristic of absorbing hydrogen with decrease in temperature of the layer; and
providing a conductive plug in the opening.

11. The method of claim 10 wherein the layer has the characteristic of releasing hydrogen therefrom with increase in temperature of the layer.

12. The method of claim 10 wherein the conductive plug is in contact with the layer.

13. The method of claim 10 wherein the layer is a conductive layer.

14. The method of claim 13 wherein the layer comprises tantalum.

15. The method of claim 14 wherein the conductive plug comprises tungsten.

16. The method of claim 10 and further comprising undertaking a processing step at an elevated temperature subsequent to providing the conductive plug in the opening.

17. The method of claim 10 wherein the dielectric body comprises silicon dioxide.

18. The device of claim 1 and further comprising said device incorporated in a system.

19. The device of claim 18 wherein the system is selected from the group consisting of a hand-held device, a vehicle, and a computer.
